(19) United States
(12) Patent Application Publication
(10) Pub. No.: US 2020/0144521 A1
(43) Pub. Date: May 7, 2020

(54) FLEXIBLE SUBSTRATE, METHOD OF FABRICATING SAME, AND DISPLAY PANEL

(71) Applicant: Wuhan China Star Optoelectronics Technology Co., Ltd., Wuhan (CN)

(72) Inventor: Bingkun YIN, (US)

(21) Appl. No.: 16/339,371

(22) PCT Filed: Nov. 29, 2018
(86) PCT No.: PCT/CN2018/118112

§ 371 Date: Apr. 4, 2019

(30) Foreign Application Priority Data
Oct. 19, 2018 (CN) 201811218871.5

(51) Int. Cl. H01L 51/00; H01L 51/56; G02F 1/1333

(52) U.S. Cl. CPC H01L 51/0097; H01L 51/56; G02F 1/133514; G02F 1/133305; H01L 2251/5338; H01L 51/003

(57) ABSTRACT

The present invention provides a flexible substrate, a method of fabricating the flexible substrate and a display panel. The present invention has the advantages that the bendable region of the flexible substrate forms a curved section in the same direction as the bendable direction of the bendable region, thereby reducing the stress of the flexible substrate in the region and reducing the risk of breakage of individual layers of the flexible substrate when bent.

### BACKGROUND OF INVENTION

### Field of Invention

The present invention relates to the field of display devices, and in particular, to a flexible substrate, a method for fabricating the flexible substrate, and a display panel.

### Description of Prior Art

In the current mobile terminal market, design requirements for high-screen ratios are getting higher and higher. How to compress non-display area borders on a display panel design has become the focus of manufacturers' designs.

One conventional method for reducing a width of the display panel border is realized by bending the non-display area to a back surface of the display panel. FIG. 1 is a schematic view showing a structure of a conventional display panel. Referring to FIG. 1, the display panel has a display area A and a non-display area B. The non-display area B is bent toward a back surface of the display panel to form a bending area C. At the bendable region C, a plurality of functional layers, for example, metal traces 11 are further provided on a substrate 10 of the display panel. When the non-display area B is bent to the back surface of the display panel, each of the functional layers at an outer portion with respect to the center of the curved curvature is subjected to stress.

In the conventional flexible array substrate, an interface between the substrate 10 and each functional layer and an interface between the adjacent functional layers are substantially planar, and therefore, the interface is substantially straight in a section where the bending direction is located. If materials or functional structures of the functional layers at the outer portion have high tensile strength or is not easily deformed, the materials or the functional structures of the functional layers may have a large stress at the bendable region C, causing damage to the functional layers or functional structures, thereby impairing the display effect.

### SUMMARY OF INVENTION

An object of the present invention is to provide a flexible substrate, a method of fabricating a flexible substrate, and a display panel capable of reducing the risk of breakage of each layer of the flexible substrate when the flexible substrate is bent.

In order to solve the above problem, the present invention provides a flexible substrate including at least one non-bendable region and at least one bendable region, wherein the flexible substrate has at least one curved section, and a curved direction of the curved section is consistent with a bendable direction of the bendable region.

In an embodiment, a curvature of the curved section is the same as a curvature of the bendable region after the bendable region is bent.

In an embodiment, the flexible substrate further includes a flexible base and a plurality of functional layers disposed on the flexible base, wherein at least a portion of the functional layers extends to the bendable region of the flexible substrate, and the flexible base and the functional layers are both curved at the curved section.

In an embodiment, the functional layers extending to the bendable region includes a metal trace layer.

In an embodiment, the functional layers include a thin film transistor layer disposed in the non-bending region.

In an embodiment, the flexible substrate includes two non-bending regions, and the bendable region is disposed between the two non-bending regions.

The present invention also provides a method of fabricating the above flexible substrate, which includes the following steps: providing a support plate including at least a first region and at least a second region; forming at least one protrusion of a curved shape in the second region of the support plate; forming a flexible substrate layer on a surface of the support plate and a surface of the protrusion, wherein a region of the flexible substrate layer corresponding to the first region is a non-bending region, while a region of the flexible substrate layer corresponding to the second region is a bendable region, and the flexible substrate layer forms a curved section at a position corresponding to the protrusion; and removing the support plate and the protrusion to form the flexible substrate.

In an embodiment, the step of forming at least one protrusion of a curved shape in the second region of the support plate includes: coating a pad on the second region of the support plate; and heat-curing the pad to form the protrusion.

In an embodiment, a curvature of the curved section is consistent with a curvature of the bendable region after the bendable region is bent.

In an embodiment, the step of forming a flexible substrate layer on a surface of the support plate and a surface of the protrusion includes the following steps: forming a flexible base layer on a surface of the support plate and a surface of the protrusion; and forming a plurality of functional layers on the flexible base layer, wherein at least a portion of the functional layers extends to the bendable region of the flexible substrate, and the flexible base and the functional layers are both curved at the curved section.

In an embodiment, the functional layers extending to the bendable region include a metal trace layer.

In an embodiment, the functional layers include a thin film transistor layer disposed in the non-bending region.

In an embodiment, the flexible substrate includes two non-bending regions, and the bendable region is disposed between the two non-bending regions.

The present invention also provides a display panel, a display layer is disposed on the flexible substrate.

In an embodiment, the display layer includes a liquid crystal layer and a color filter substrate, and the liquid crystal layer is disposed between the flexible substrate and the color filter substrate.

In an embodiment, the display layer includes an organic light emitting layer.

The present invention has the advantages that the bendable region of the flexible substrate forms a curved section in the same direction as the bendable direction of the bendable region, thereby reducing a stress of the flexible substrate in the region and reducing a risk of breakage of each layer of the flexible substrate.

### BRIEF DESCRIPTION OF THE DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is schematic view showing a structure of a conventional display panel;

FIG. 2 is a side view of an embodiment of a flexible substrate according to the present invention;

FIG. 3 is a top view of another embodiment of a flexible substrate according to the present invention;

FIG. 4 is a schematic view showing an embodiment of a flexible substrate after the flexible substrate is bent according to the present invention;

FIG. 5 is a side view showing another embodiment of a flexible substrate according to the present invention;

FIGS. 6A-6E are process flow diagrams of an embodiment of a method of fabricating a flexible substrate according to the present invention;

FIG. 7 is a schematic view showing a structure of an embodiment of a display panel according to the present invention; and

FIG. 8 is a schematic view showing a structure of another embodiment of the display panel according to the present invention.

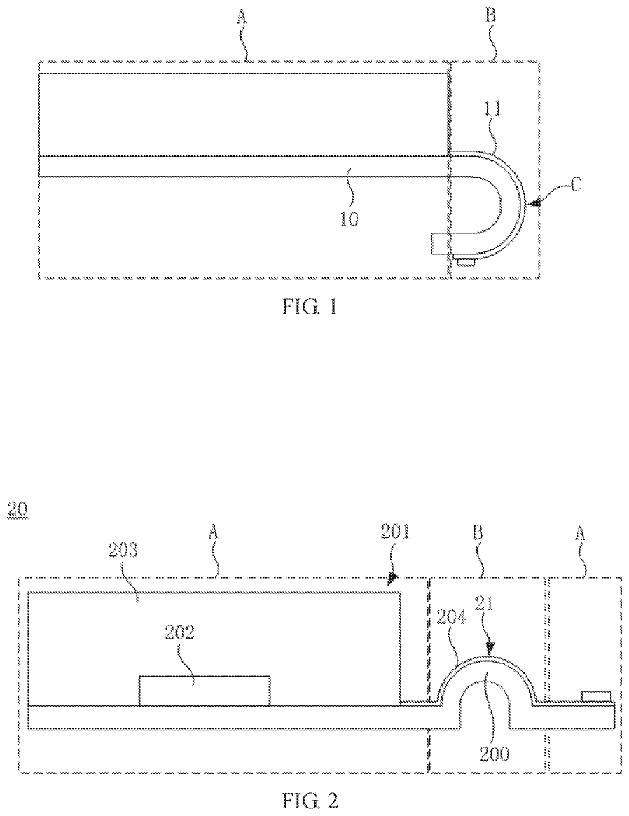

### DETAILED DESCRIPTION OF PREFERRED EMBODIMENTS

Specific embodiments of a flexible substrate, a method for fabricating the flexible substrate, and a display panel provided by the present invention will be described in detail below with reference to the accompanying drawings.

FIG. 2 is a schematic structural view of an embodiment of a flexible substrate according to the present invention. Referring to FIG. 2, the flexible substrate 20 of the present invention includes at least one non-bendable region A and at least one bendable region B. The non-bendable region refers to an area which is not bent when an external force is applied to the flexible substrate 20, while the bendable region refers to an area which is bendable when an external force is applied to the flexible substrate 20. In the embodiment, the flexible substrate 20 includes two non-bending regions A and one bendable region B between the two non-bending regions A.

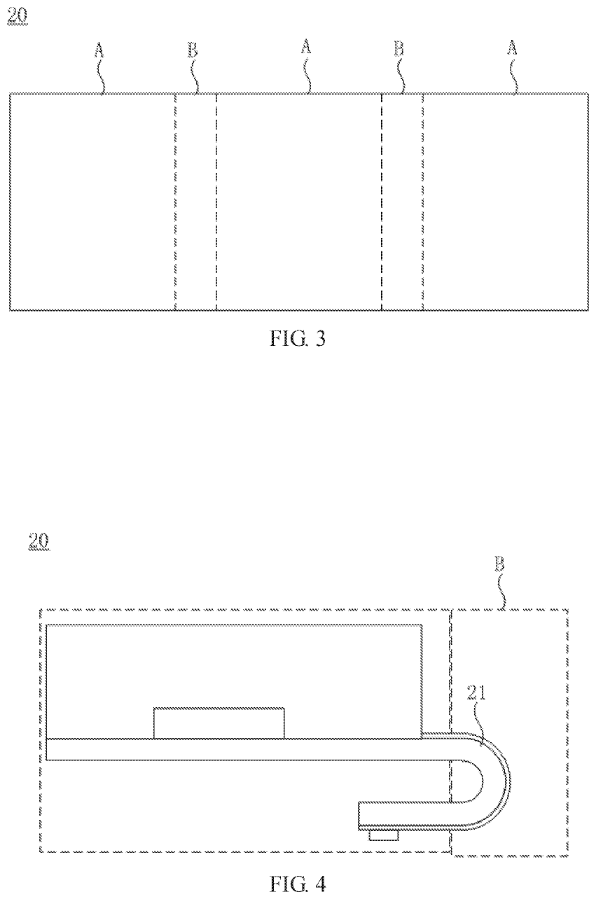

The flexible substrate 20 may include a plurality of non-bending regions A and a plurality of bendable regions B that are alternately arranged, but the invention is not limited thereto. For example, referring to FIG. 3, in another embodiment of the present invention, the flexible substrate 20 includes three non-bending regions A and two bendable regions B arranged alternately, wherein FIG. 3 is a top view of the flexible substrate 20.

Referring to FIG. 2, in the bendable region B, the flexible substrate 20 has at least one curved section 21. The curved direction of the curved section 21 is the same as the bendable direction of the bendable region B. The bendable direction of the bendable region B refers to a direction of stress transmission when the bendable region B is bent. Because the curved direction of the curved section 21 is the same as the bendable direction of the bendable region B, when the bendable region B is bent, stress of the flexible substrate in the region can be reduced, thereby reducing the risk of breakage of the individual layers of the flexible substrate 20 when the flexible substrate 20 is bent. The curved shape of the curved section 21 includes, but is not limited to, an arc shape.

In this embodiment, the flexible substrate 20 has a curved section 21. A curvature of the curved section 21 is the same as a curvature of the bendable region B after the flexible substrate is bent. FIG. 4 is a schematic view of an embodiment of a flexible substrate after the flexible substrate is bent according to the present invention. Referring to FIG. 4, when the bendable region B is bent, one end of the flexible substrate 20 is bent toward the back surface of the flexible substrate 20 with a center of the curved section 21 as a bending axis. As a result, the stress of each layer in the bendable region B of the flexible substrate 20 is reduced.

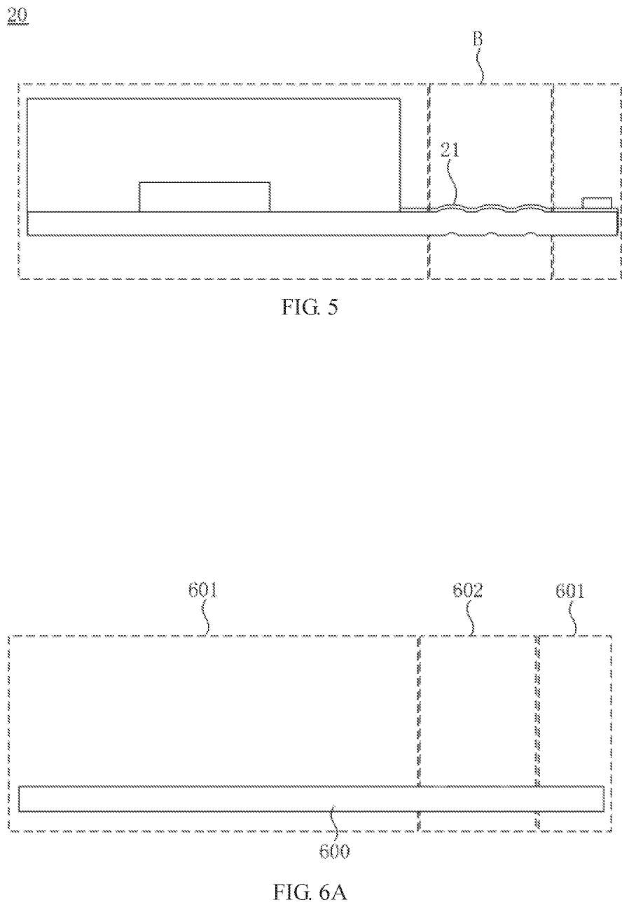

The number of the curved sections 21 is not particularly limited in the present invention. For example, referring to FIG. 5, in another embodiment of the present invention, in the bendable region B, the flexible substrate 20 includes three curved sections 21. When performing the bending operation on the bendable region B, preferably, one end of the flexible substrate 20 is bent toward the back surface of the flexible substrate 20 with the center of the three curved sections 21 as a bending axis, thereby reducing the stress of the flexible substrate 20 in each layer of the bendable region B.

The flexible substrate 20 of the present invention may be bent at various positions including the display area, and thus can be used to manufacture a flexible display panel; or can be bent mainly at a non-display area such as an edge, and thus can be used, for example, to manufacture a display panel with a narrow border.

Further, please still refer to FIG. 2. In this embodiment, the flexible substrate 20 further includes a flexible base 200 and a plurality of functional layers 201 disposed on the flexible base 200.

The flexible base 200 may be made of a polymer, such as polyimide (PI), polycarbonate (PC), polyethersulfone (PES), polyethylene terephthalate (PET), polyethylene naphthalate, polymer materials such as (PEN), polyarylate (PAR) or glass fiber reinforced plastic (FRP), and the like. Functional layers 201 refer to various layers such as a driving circuit layer, a metal trace layer, a gate layer, a gate dielectric layer, a source/drain layer, a semiconductor material layer, a passivation layer, and the like, which are constructed to realize a display function of the displaying layers such as an organic electroluminescent layer, a liquid crystal layer, a plasma layer, and an electronic ink layer. Functional layers 201 may be formed on the flexible base 200 by semiconductor fabrication processes well known to those skilled in the art, including, but are not limited to, photolithography, etching, coating, sputtering, vapor deposition, doping, and the like.

At least a portion of the functional layers 201 extends to the bendable region B of the flexible substrate 20, and the flexible base 200 and the functional layers 201 are each in a curved configuration. The functional layers 201 extending to the bendable region B of the flexible substrate 20 include, but are not limited to, a metal trace layer, a buffer layer, a passivation layer, and the like. In this embodiment, the functional layers 201 extending to the bendable region B of the flexible substrate 20 include the metal trace layer 204. In the bendable region B, because the flexible base 200 and the functional layers 201 are both curved in the curved section 21, when they are bent, the stress of the functional layers 201 in the bendable region can be reduced, thereby reducing the risk of breakage of each functional layer 201 when functional layers 201 are bent. The functional layers 201 further include a thin film transistor layer 202 disposed in the non-bendable region A. Further, the thin film transistor layer 202 is further covered with an alignment layer 203. The functional layers 201 are conventional structures in the art, and details are not repeated herein for brevity.

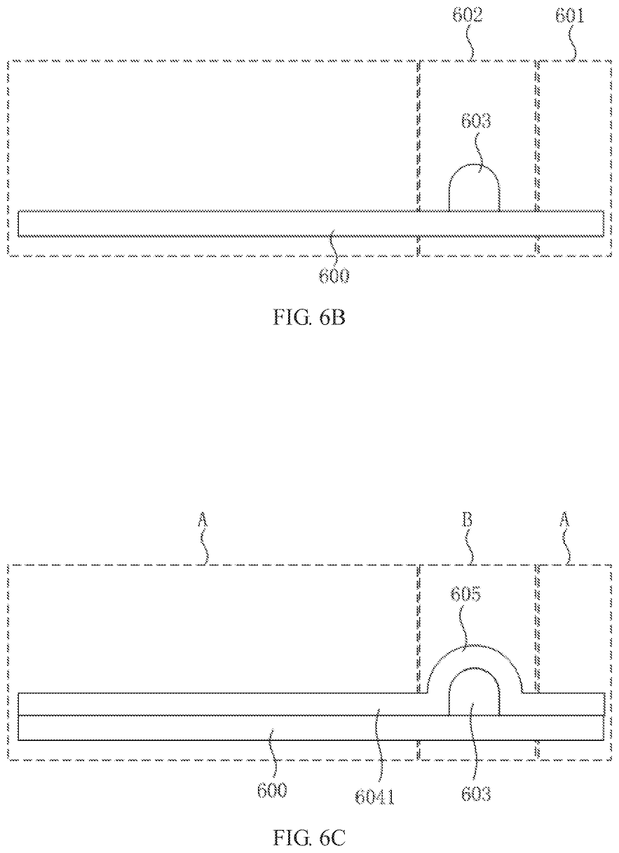

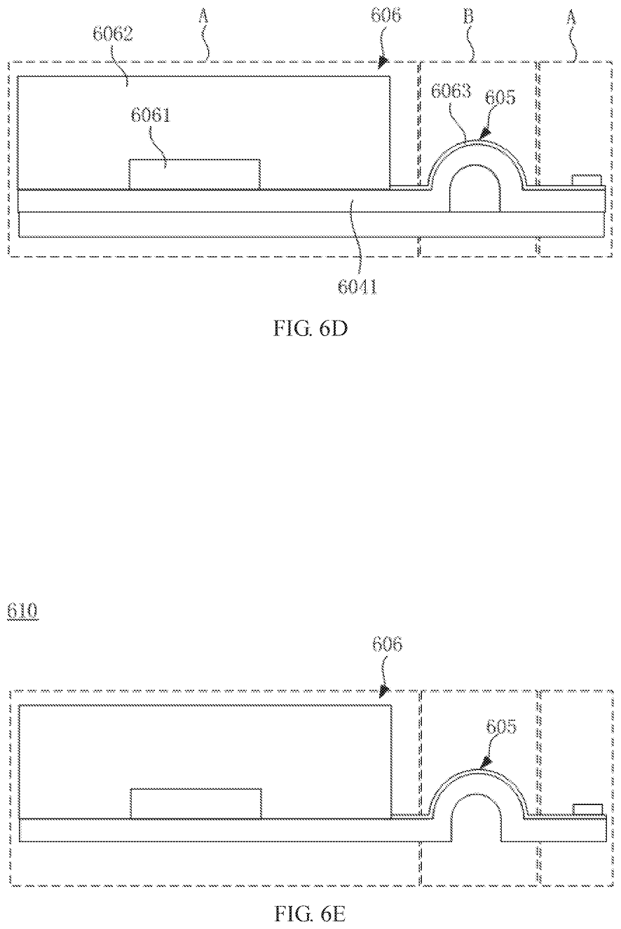

The present invention also provides a method of fabricating the above-mentioned flexible substrate. FIGS. 6A-6E are process flow diagrams of an embodiment of a method of fabricating a flexible substrate according to the present invention.

Referring to FIG. 6A, a support plate 600 is provided. The support plate 600 includes at least one first region 601 and at least one second region 602. The support plate 600 includes, but is not limited to, a support plate such as a glass substrate conventionally used in the display field. In this embodiment, the support plate 600 is divided into two first regions 601 and a second region 602, and the second region 602 is located between the two first regions 601. In other embodiments of the present invention, the support plate 600 may also be divided into a plurality of the first regions 601 and the second regions 602 which are alternately arranged.

Referring to FIG. 6B, at least one protrusion 603 in a curved shape is formed in the second region 602 of the support plate 600. Specifically, a method of forming at least one protrusion 603 in a curved shape in the second region 602 of the support plate 600 is applying a spacer to the second region 602 of the support plate 600, and heat curing the spacer, to form the protrusion 603. The shape of the protrusion 603 is the same as the shape of the curved section 605 (as shown in FIG. 6C) to be formed later.

Referring to FIG. 6C and FIG. 6D, a flexible substrate layer is formed on the surface of the support plate 600 and the surface of the protrusion 603. A region of the flexible substrate layer corresponding to the first region 601 is a non-bendable region A, and a region of the flexible substrate layer corresponding to the second region 602 is a bendable region B. In this embodiment, the flexible substrate layer includes two non-bending regions A and one bendable region B, and the bendable regions B are disposed between the two non-bending regions A.

In this step, the flexible substrate layer is not specifically limited to a single layer structure, and it may be a single layer structure or a multilayer structure. For example, in this embodiment, the flexible substrate layer has a multilayer structure including a flexible base layer 6041 and a plurality of functional layers 606. The functional layers include, but are not limited to, a thin film transistor layer 6061, an alignment layer 6062, and a metal trace layer 6063. The description of the functional layers can be referred to the above, and details are not repeated herein for brevity.

The flexible substrate layer forms the curved section 605 at a position corresponding to the protrusion 603. In this step, due to the presence of the protrusion 603 on the support plate 600, when the flexible substrate layer is formed, a curved section 605 of the flexible substrate layer is naturally formed at the protrusion 603 according to the contour of the protrusion 603.

Specifically, in the embodiment, the method of forming the flexible substrate layer on the surface of the support plate 600 and the surface of the protrusion 603 includes the following steps:

(1) Referring to FIG. 6C, the flexible substrate layer 6041 is formed on the surface of the support plate 600 and the surface of the protrusion 603. Specifically, the flexible base layer 6041 may be made of a polymeric material including polyimide (PI), polycarbonate (PC), polyethersulfone (PES), polyethylene terephthalate (PET), polynaphthalene dicarboxylic ethylene glycol ester (PEN), polyarylate (PAR) or a glass fiber reinforced plastic (FRP). For example, in the present embodiment, the flexible substrate layer 6041 can be formed by coating a surface of the support plate 600 and a surface of the protrusion 603 with a polyimide layer.

(2) Referring to FIG. 6D, a plurality of functional layers 606 are formed on the flexible base layer 6041. At least a portion of the functional layers 606 extends to the bendable region B of the flexible substrate layer, and the flexible substrate and the functional layers are each in a curved configuration. That is, a portion of the functional layers 606 is located at the non-bendable region A, and a portion of the functional layers 606 extends to the bendable region B. Specifically, in this embodiment, the thin film transistor layer 6061 and the alignment layer 6062 are located at the non-bendable region A, and the metal trace layer 6063 extends to the bendable region B. In other embodiments, other functional layers may also be formed depending on different applications of the flexible substrate of the present invention.

Referring to FIG. 6E, the support plate 600 and the protrusion 603 are removed to form the flexible substrate 610. Specifically, the support plate 600 and the protrusion 603 may be removed by laser lift-off or the like to form a flexible substrate 610 having a curved section 605.

Optionally, depending on different applications of the flexible substrate 610 of the present invention, the step of forming other structures is further performed before the support plate 600 and the protrusion 603 are removed, wherein the support plate 600 provides support functions. Specifically, if the flexible substrate 610 is used as the array substrate of the liquid crystal display device, before the step of removing the support plate 600 and the protrusion 603, the method further includes: a step of assembling a color filter substrate and the flexible substrate 610 into a cell and filling the cell with liquid crystal. These steps are conventional, and details are not repeated herein for brevity.

According to the method of fabricating the flexible substrate of the present invention, the curved section 605 can be formed at the bendable region B of the flexible substrate 610, thereby reducing the stress of the functional layers 606 located at this region, and reducing a risk of breakage of the various functional films when they are bent.

The flexible substrate of the present invention can be applied to an organic light emitting diode (OLED) display device, a liquid crystal display (LCD), a plasma display panel (PDP), or an electronic ink display device. For example, the flexible substrate can be used as a carrier and a driving unit of an organic electroluminescent material, a liquid crystal, a plasma or an electronic ink, and a displaying layer such as an organic electroluminescent material layer, a liquid crystal layer, a plasma layer or an electronic ink layer can be formed on the functional layers to fabricate a corresponding display panel. Meanwhile, those skilled in the art can readily appreciate that the flexible array substrate of the present invention may also be applied to other technical fields in addition to the display field. In such cases, the functional layers refer to various layers required for realizing other target functions.

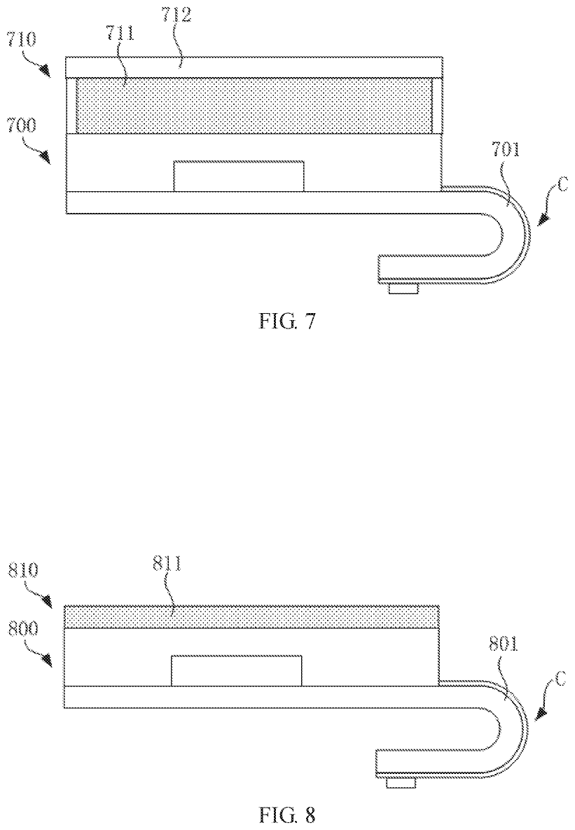

The present invention also provides a display panel. FIG. 7 is a schematic structural view of an embodiment of a display panel of the present invention. Referring to FIG. 7, the display panel includes a flexible substrate 700 as described above, and a display layer 710 is disposed on the flexible substrate 700. In this embodiment, the display layer 710 includes a liquid crystal layer 711 and a color filter substrate 712. The liquid crystal layer 711 is disposed between the flexible substrate 700 and the color filter substrate 712. The display panel is an LCD display panel. At one end of the display panel, such as a lower border, the flexible substrate 700 is bent toward the back surface of the display panel. At the bendable region C, because the flexible substrate 700 has the curved section 701, the stress of the functional layers at the region is reduced, and the risk of breakage of each functional layer is reduced. Other structures of the display panel are conventional, and details are not repeated herein for brevity.

FIG. 8 is a schematic view of the structure of the display panel according to another embodiment of the present invention. Referring to FIG. 8, the display panel includes a flexible substrate 800 as described above, and a display layer 810 is disposed on the flexible substrate 800. In this embodiment, the display layer 810 includes an organic light emitting layer 811. In this embodiment, the display panel is an OLED display panel. At one end of the display panel, such as a lower border, the flexible substrate 800 is bent toward the back surface of the display panel. At the bendable region C, because the flexible substrate 800 has the curved section 801, the stress of the functional layers at the region is reduced, and the risk of breakage of each functional layer is reduced. Other structures of the display panel are conventional, and details are not repeated herein for brevity.

While the invention has been described by way of example and in terms of the preferred embodiments, it is to be understood that the invention is not limited to the disclosed embodiments. To the contrary, it is intended to cover various modifications and similar arrangements. Therefore, the scope of the appended claims should be accorded the broadest interpretation so as to encompass all such modifications and similar arrangements.

The subject matter of the present application can be manufactured and used in the industry with industrial applicability.

What is claimed is:

1. A flexible substrate, comprising at least one non-bending region and at least one bendable region, wherein the flexible substrate has at least one curved section, and a curved direction of the curved section is consistent with a bendable direction of the bendable region.

2. The flexible substrate of claim 1, wherein a curvature of the curved section is the same as a curvature of the bendable region after the bendable region is bent.

3. The flexible substrate of claim 1, further comprising a flexible base and a plurality of functional layers disposed on the flexible base, wherein at least a portion of the functional layers extends to the bendable region of the flexible substrate, and the flexible base and the functional layers are both curved at the curved section.

4. The flexible substrate of claim 3, wherein the functional layers extending to the bendable region comprises a metal trace layer.

5. The flexible substrate of claim 3, wherein the functional layers comprise a thin film transistor layer disposed in the non-bending region.

6. The flexible substrate of claim 1, wherein the flexible substrate comprises two non-bending regions, and the bendable region is disposed between the two non-bending regions.

7. A method of fabricating the flexible substrate according to claim 1, comprising the following steps:
providing a support plate comprising at least a first region and at least a second region;
forming at least one protrusion of a curved shape in the second region of the support plate;
forming a flexible substrate layer on a surface of the support plate and a surface of the protrusion, wherein a region of the flexible substrate layer corresponding to the first region is a non-bending region, while a region of the flexible substrate layer corresponding to the second region is a bendable region, and the flexible substrate layer forms a curved portion at a position corresponding to the protrusion; and
removing the support plate and the protrusion to form the flexible substrate.

8. The method of fabricating a flexible substrate according to claim 7, wherein the step of forming at least one protrusion of a curved shape in the second region of the support plate comprises:
coating a pad on the second region of the support plate; and
heat-curing the pad to form the protrusion.

9. The method of fabricating a flexible substrate according to claim 7, wherein a curvature of the curved section is consistent with a curvature of the bendable region after the bendable region is bent.

10. The method of fabricating a flexible substrate according to claim 7, wherein the step of forming a flexible substrate layer on a surface of the support plate and a surface of the protrusion comprises the following steps:
forming a flexible base layer on a surface of the support plate and a surface of the protrusion;
forming a plurality of functional layers on the flexible base layer, wherein at least a portion of the functional layers extends to the bendable region of the flexible substrate, and the flexible base and the functional layer are both curved at the curved section.

11. The method of fabricating a flexible substrate according to claim 10, wherein the functional layers extending to the bendable region comprise a metal trace layer.

12. The method of fabricating a flexible substrate according to claim 10, wherein the functional layers comprise a thin film transistor layer disposed in the non-bending region.

13. The method of fabricating a flexible substrate according to claim 7, wherein the flexible substrate comprises two non-bending regions, and the bendable region is disposed between the two non-bending regions.

14. A display panel comprising the flexible substrate of claim 1, wherein a display layer is disposed on the flexible substrate.

15. The display panel of claim 14, wherein the display layer comprises a liquid crystal layer and a color filter substrate, and the liquid crystal layer is disposed between the flexible substrate and the color filter substrate.

16. The display panel of claim 14, wherein the display layer comprises an organic light emitting layer.
